(19) United States
(12) Patent Application Publication
(10) Pub. No.: US 2015/0249177 A1
(43) Pub. Date: Sep. 3, 2015

(54) SOLAR-CELL MODULE

(71) Applicant: Panasonic Intellectual Property Management Co., Ltd., Osaka (JP)

(72) Inventors: Yosuke ISHII, Osaka (JP); Masaki YOSHIDA, Nara (JP)

(21) Appl. No.: 14/712,171

(22) Filed: May 14, 2015

Related U.S. Application Data
(63) Continuation of application No. PCT/JP2013/080547, filed on Nov. 12, 2013.

(30) Foreign Application Priority Data
Nov. 30, 2012 (JP) 2012-262353

(51) Int. Cl. H01L 31/05

(52) U.S. Cl. CPC H01L 31/0508

(57) ABSTRACT

A solar cell module is provided that comprises solar cells comprising a first solar cell and a second solar cell, the first solar cell and the second solar cell are arranged at intervals from each other in a first direction, and each including first and second electrodes on one principal surface; and an interconnection wiring sheet electrically connecting the first electrode of the first solar cell and the second electrode of the second solar cell that is positioned adjacent to the first solar cell. The interconnection wiring sheet extends from part of the first solar cell to part of the second solar cell, and covers at least part of a space between the first and second solar cells, and an opening is formed in an area in the interconnection wiring sheet covering the space.

### CROSS REFERENCE TO RELATED APPLICATIONS

This application is a continuation application of International Application No. PCT/JP2013/080547, filed on Nov. 12, 2013, entitled “SOLAR-CELL MODULE”, which claims priority based on the Article 8 of Patent Cooperation Treaty from prior Japanese Patent Application No. 2012-262353, filed on Nov. 30, 2012, the entire contents of which are incorporated herein by reference.

### BACKGROUND

The disclosure relates to a solar cell module.

In recent years, solar cell modules including back contact solar cells have been known as solar cell modules having outstanding photoelectric conversion efficiency. For example, Japanese Patent Application Publication No. 2009-266848 (Patent Document 1) describes a solar cell module, which includes back contact solar cells electrically connected together with interconnection wiring members. In the solar cell module described in Patent Document 1, each of rectangular interconnection wiring members is bonded to two solar cells while extending from one side end to the opposed side end of the solar cells in a direction vertical to an array direction of the solar cells.

### SUMMARY

When the temperature of the solar cell module changes, spaces between the solar cells may change due to the difference in coefficient of linear expansion between the protective members and the solar cells . Once the spaces between the solar cells and protective members change, stress occurs in the interconnection wiring members connected to the solar cells. This stress works as a factor in making the interconnection wiring members come off the solar cells. For this reason, a problem to be solved for the solar cell module is how to inhibit the reliability of the solar cell module from worsening due to the stress caused in the interconnection wiring members.

A solar cell module of an embodiment comprises solar cells comprising a first solar cell and a second solar cell, the first solar cell and the second solar cell arranged at intervals from each other in a first direction, and each including first and second electrodes on one principal surface; and an interconnection wiring sheet electrically connecting the first electrode of the first solar cell and the second electrode of the second solar cell that is positioned adjacent to the first solar cell, wherein the interconnection wiring sheet extends from part of the first solar cell to part of the second solar cell, and covers at least part of a space between the first and second solar cells, and an opening is formed in an area in the interconnection wiring sheet covering the space.

### BRIEF DESCRIPTION OF THE DRAWINGS

FIG. 1 is a schematic cross-sectional view of a solar cell module of an embodiment.

FIG. 2 is a schematic rear view of a solar cell of the embodiment.

FIG. 3 is a schematic rear view of a solar cell string of the embodiment.

FIG. 4 is a schematic cross-sectional view of the solar cell string taken along the IV-IV line of FIG. 3.

FIG. 5 is a schematic rear view of a solar cell string of a first modification.

### DESCRIPTION OF THE EMBODIMENTS

Descriptions are hereinbelow provided for an example of an embodiment. It should be noted that the following embodiment is shown just as an example. The invention is not limited to the following embodiment at all.

Furthermore, throughout the drawings referred to in the embodiment and the like, members having virtually the same functions are denoted by the same reference signs. In addition, the drawings referred to in the embodiment and the like are schematically illustrated, and dimensional ratios and the like of objects depicted in the drawings are not necessarily the same as those of real objects. Dimensional ratios and the like of the same objects may differ from one drawing to another as well. Concrete dimensional ratios and the like have to be judged with the following descriptions taken into consideration.

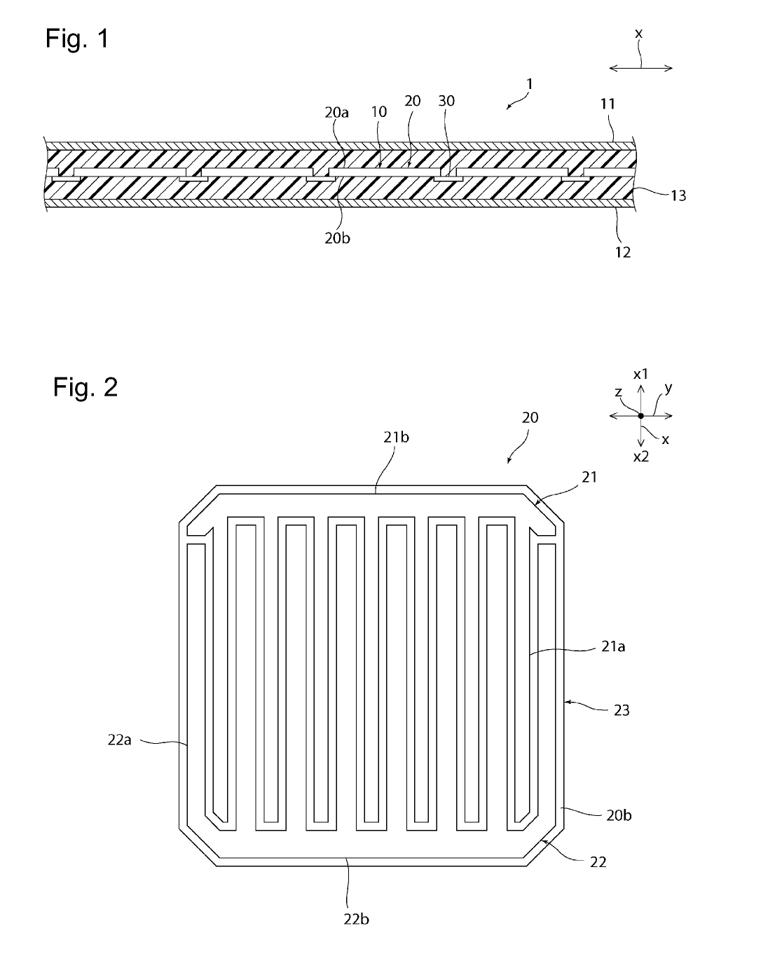

As illustrated in FIG. 1, solar cell module 1 includes solar cell string 10. Solar cell string 10 is disposed between first protective member 11 placed on a light-receiving surface side and second protective member 12 placed on a back surface side. Bonding layer 13 is provided between first protective member 11 and second protective member 12. Solar cell string 10 is sealed with bonding layer 13.

First protective member 11 may be made of a glass plate, a ceramic plate, or the like, for example. Second protective member 12 maybe made of a resin sheet, a resin sheet with metal foil inserted in it, or the like, for example. Bonding layer 13 maybe made of ethylene-vinyl acetate copolymer (EVA) resin, polyvinyl butyral (PVB) resin, polyethylene (PE) resin, polyurethane (PU) resin, or the like, for example.

Solar cell string 10 includes solar cells 20 arranged at intervals from each other in an x-axis direction (first direction). Solar cell 20 has first and second principal surfaces 20a, 20b. In solar cell 20, first principal surface 20a receives light. For this reason, first and second principal surfaces 20a, 20b are referred to as a light-receiving surface and a back surface, respectively, from time to time. It is desirable to use solar cells 20 in each of which only first principal surface 20a, forming the light-receiving surface, receives light and generates power. Nevertheless, double-sided light-receiving solar cells may be used in each of which both first and second principal surfaces 20a, 20b receive light and generate power.

It should be noted that no specific restriction is imposed on what type solar cells 20 are of. Solar cells 20 may be each made of a crystalline silicon solar cell using a crystalline silicon substrate.

As illustrated in FIG. 2, solar cells 20 each include: photoelectric conversion body 23; and first and second electrodes 21, 22 disposed on a principal surface on the side of the back surface of photoelectric conversion body 23.

First electrode 21 includes finger portions 21a and bus bar portion 21b. Each finger portion 21a extends in the x-axis direction. Finger portions 21a are electrically connected to bus bar portion 21b. Bus bar portion 21b is disposed on one sides (x1 sides) of finger portions 21a in the x-axis direction. Bus bar portion 21b is provided to the x1 side end portion of solar cell 20 in the x-axis direction, and extends from one side end portion to an opposite side end portion of solar cell 20 in the y-axis direction.

Second electrode 22 includes finger portions 22a and bus bar portion 22b. Each finger portion 22a extends in the x-axis direction. Finger portions 21a alternate with finger portions 22a in the y-axis direction. Finger portions 22a are electrically connected to bus bar portion 22b. Bus bar portion 22b is disposed on opposite sides (x2 sides) of finger portions 22a in the x-axis direction. Bus bar portion 22b is provided to the x2 side end portion of solar cell 20 in the x-axis direction, and extends from the one side end portion to the opposite side end portion of solar cell 20 in the y-axis

As illustrated in FIGS. 1, 3 and 4, solar cells 20 are electrically connected together with interconnection wiring member 30. To put it concretely, of solar cells 20 adjacent to each other in the x-axis direction, first electrode 21 of one solar cell 20 and second electrode 22 of the other solar cell 20 are electrically connected together with interconnection wiring member 30.

As illustrated in FIG. 4, interconnection wiring member 30 includes conduction layer 31 and resin sheet 32. Conduction layer 31 is stacked on resin sheet 32, and is supported by resin sheet 32. Interconnection wiring member 30 is disposed covering a region from part of first electrode 21 of the one solar cell 20 through part of second electrode 22 of the other solar cell 20. Interconnection wiring member 30 is disposed in a way that makes conduction layer 31 and solar cells 20 face each other.

Of solar cells 20 adjacent to each other in the x-axis direction, conduction layer 31 electrically connects first electrode 21 of the one solar cell 20 and second electrode 22 of the other solar cell 20. Conduction layer 31 may be made of appropriate conduction materials. To put it concretely, conduction layer 31 may be made of at least one selected from a group consisting of Cu, Ag, Au, Pt, Ni and Sn, for example. Conduction layer 31 may have a thickness of approximately 8 μm to 80 μm, for example.

Resin sheet 32 may be made of at least one selected from a group consisting of polyimide, polyethylene terephthalate (PET), polyethylene naphthalate (PEN) and polyethylene (PE), for example. Resin sheet 32 may have a thickness of approximately 1 μm to 50 μm, for example. Incidentally, an adhesive layer maybe provided between conduction layer 31 and resin sheet 32.

Interconnection wiring member 30 includes first bonded portion 30a, second bonded portion 30b and connection portion 30c.

First bonded portion 30a is a part disposed on bus bar portion 22b of second electrode 22 of the other solar cell 20. Adhesive layer 40 is disposed between first bonded portion 30a and bus bar portion 22b. Interconnection wiring member 30 is bonded to bus bar portion 22b with adhesive layer 40.

Second bonded portion 30b is a part disposed on bus bar portion 21b of first electrode 21 of the one solar cell 20. Adhesive layer 40 is disposed between second bonded portion 30b and bus bar portion 21b. Interconnection wiring member 30 is bonded to bus bar portion 21b with adhesive layer 40.

Adhesive layer 40 may be made of cured resin adhesive, cured resin adhesive inclusive of conduction material, solder, or the like, for example.

Connection portion 30c is a part disposed between the one solar cell 20 and the other solar cell 20. In other words, connection portion 30c is the part between first bonded portion 30a and second bonded portion 30b. Connection portion 30c is not directly bonded to solar cells 20.

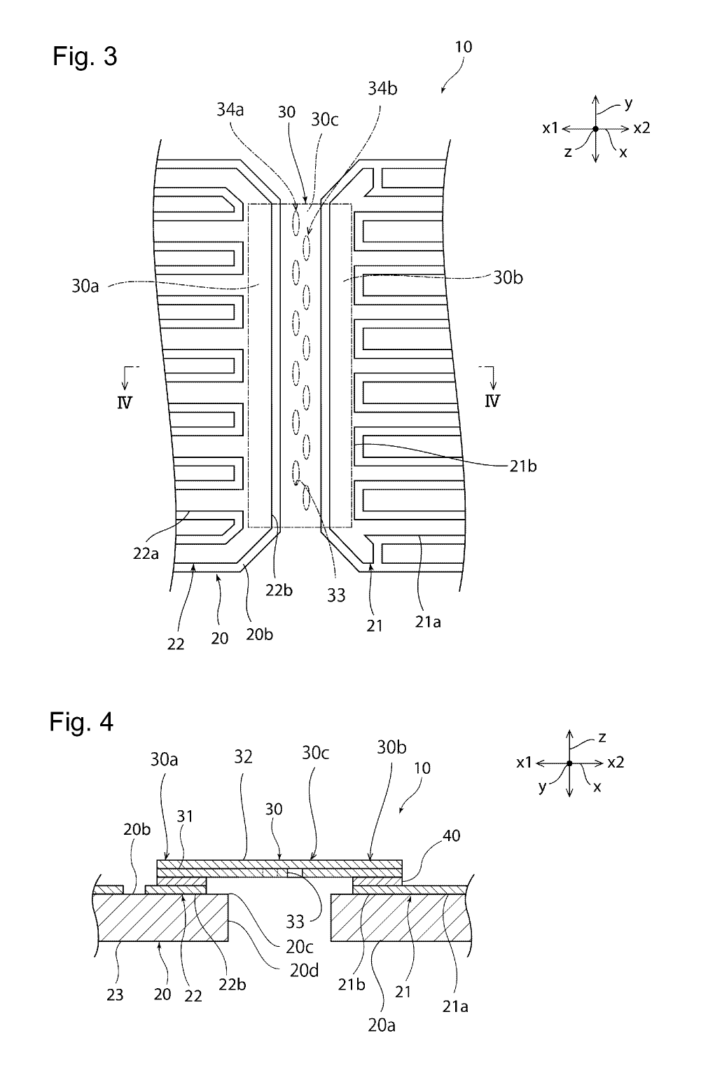

As illustrated in FIGS. 3 and 4, in connection portion 30c, two rows of openings 34a, 34b are formed in conduction layer 31. Rows of openings 34a, 34b are disposed in parallel in the x-axis direction. Rows of openings 34a, 34b each include openings 33 which are arranged at intervals from each other in the y-axis direction. Rows of openings 34a, 34b are disposed in a way that neither of rows of openings 34a, 34b is situated above any of solar cells 20. To put it concretely, as illustrated in FIG. 4, rows of openings 34a, 34b are disposed away from corner portions 20c where side surfaces 20d opposed to adjacent solar cells 20 and back surfaces 20b of solar cells 20 join each other, respectively, by a predetermined distance in the x-axis direction.

Openings 33 are through-holes formed in conduction layer 31, and are shaped like an ellipse whose major axis extends in the y-axis direction. Openings 33 included in row of openings 34a and openings 33 included in row of openings 34b are disposed in a way that openings 33 included in row of openings 34a are not located in the same row extending in the x-axis direction as openings 33 included in row of openings 34b, and vice versa. In other words, openings 33 included in row of openings 34a and openings 33 included in row of openings 34b are staggered in the y-axis direction. Incidentally, it is desirable that openings 33 be shaped like at least one of a corner-rounded rectangle, a circle, an ellipse, and an elongated circle.

In the embodiment, as described above, of adjacent solar cells 20, conduction layer 31 extends from part of the one solar cell 20 to part of the other solar cell 20, and covers at least part of the space between the one and other solar cells 20. Conduction layer 31 is provided with openings 33 in an area covering the space, namely in connection portion 30c. Thereby, it is possible to increase the stretchability of connection portion 30c. For this reason, even when a change in the space between adjacent solar cells 20 applies stress to interconnection wiring member 30, the stretch and contraction of connection portion 30c makes it possible to inhibit interconnection wiring member 30 from coming off solar cells 20. This makes it possible to realize solar cell module 1 with improved reliability.

Furthermore, in the embodiment, as illustrated in FIG. 4, rows of openings 34a, 34b are disposed away from corner portions 20c where side surfaces 20d opposed to adjacent solar cells 20 and back surfaces 20b of solar cells 20 join each other, respectively, by the predetermined distance in the x-axis direction. This makes it possible to inhibit corner portions 20c of solar cells 20 from coming into contact with conduction layer 31 when the temperature of solar cell module 1 changes, and accordingly to inhibit damage from accumulating in connection portion 30c with less strength. As a result, it is possible to inhibit the occurrence of cracks and the like in conduction layer 31 which may start with openings 33. It should be noted that when openings 33 are formed as large as possible within a range in which conduction layer 31 does not come into contact with corner portion 20c, the stretchability of interconnection wiring member 30 can be increased more.

Furthermore, in the embodiment, openings 33 are shaped like an ellipse whose major axis extends in the y-axis direction. This makes it possible to effectively increase the stretchability of interconnection wiring member 30 using the smaller number of openings 33.

Moreover, in the embodiment, two rows of openings 34a, 34b are formed disposed in parallel in the x-axis direction. When openings 33 are disposed in the multiple rows like this, openings 33 can be spaced more widely than when the same number of openings 33 are disposed in a single row in the y-axis direction. Accordingly, it is possible to decreases the risk that cracks occurs in a way that links openings 33 adjacent in the y-axis direction to one another. For this reason, the stretchability of interconnection wiring member 30 can be increased more effectively, and much higher reliability can be realized.

Besides, in the embodiment, interconnection wiring member 30 is formed by stacking conduction layer 31 on resin sheet 32, and openings 33 are formed in conduction layer 31 alone. Thereby, the stretchability of connection portion 30c can be improved while inhibiting a decrease in the rigidity of connection portion 30c provided with openings 33. In addition, since the stability of the shape of interconnection wiring member 30 can be enhanced, it is possible to enhance workability with which solar cells 20 and interconnection wiring member 30 are positioned to each other for their connection.

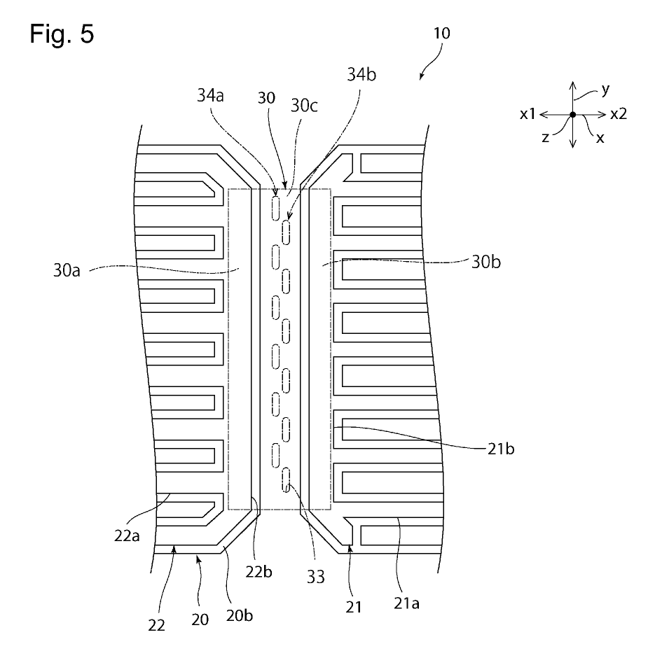

It should be noted that although in the embodiment, as illustrated in FIG. 3, openings 33 are shaped like an ellipse whose major axis extends in the y-axis direction, openings 33 may be shaped like an elongated circle whose longitudinal direction extends in the y-axis direction as illustrated in FIG. 5. Otherwise, openings 33 may be shaped like a corner-rounded rectangle whose longitudinal direction extends in the y-axis direction. In other words, it is desirable that a shape having no corner portion, or a corner-rounded (corner-curved) shape be used for openings 33. This makes it possible to more effectively inhibit damage on conduction layer 31 which may start with openings 33.

It should be noted that in the embodiment, openings 33 are formed in conduction layer 31 alone, openings 33 may be provided additionally to resin sheet 32. This makes it possible to improve the stretchability of connection portion 30c more than when openings 33 are provided to conduction layer 31 alone. Otherwise, openings 33 may be provided to resin sheet 32 alone. This case also brings about the same effects as the provision of openings 33 to conduction layer 31 alone.

In this way, the embodiments described above provide solar cell modules with improved reliability.

1. A solar cell module comprising:
solar cells comprising a first solar cell and a second solar cell, the first solar cell and the second solar cell arranged at intervals from each other in a first direction, and each including first and second electrodes on one principal surface; and
an interconnection wiring sheet electrically connecting the first electrode of the first solar cell and the second electrode of the second solar cell that is positioned adjacent to the first solar cell, wherein
the interconnection wiring sheet extends from part of the first solar cell to part of the second solar cell, and covers at least part of a space between the first and second solar cells, and
an opening is formed in an area in the interconnection wiring sheet covering the space.

2. The solar cell module according to claim 1, wherein the opening is formed at a predetermined distance from a side surface of the first solar cell opposed to the second solar cell and at a predetermined distance from a side surface of the second solar cell opposed to the first solar cell.

3. The solar cell module according to claim 2, wherein
the interconnection wiring sheet includes a plurality of the openings, and
the openings are arranged in such that the openings do not overlap each other when viewed from the first direction.

4. The solar cell module according to claim 3, wherein opening rows each including some of the openings arranged at intervals from each other in a second direction orthogonal to the first direction are provided side by side in the first direction.

5. The solar cell module according to claim 1, wherein the openings each have an elongate shape whose longitudinal direction extends in the second direction.

6. The solar cell module according to claim 1, wherein the openings have shapes including at least one of a corner-rounded rectangle, a circle, an ellipse and an elongated circle.

7. The solar cell module according to claim 1, wherein
the interconnection wiring sheet comprises:
a conduction layer connected to the first electrode of the first solar cell and the second electrode of the second solar cell; and
a resin sheet stacked on the conduction layer, wherein
the openings are arranged at the conduction layer.

8. The solar cell module according to claim 7, wherein the resin sheet covers the openings.
